(19) United States
(12) Patent Application Publication
(10) Pub. No.: US 2006/0189030 A1
(43) Pub. Date: Aug. 24, 2006

(54) Heat shrinkable insulated packaging

(76) Inventors: Jeffrey Allen Chambers, Hockessin, DE (US); Peter Veenema, Wilmington, DE (US); Mark A. Gentile, Oxford, PA (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/349,478

(22) Filed: Feb. 7, 2006

Related U.S. Application Data
(60) Provisional application No. 60/650,542, filed on Feb. 7, 2005.

(51) Int. Cl. H01L 21/50; H01L 21/20; H01L 23/02

(52) U.S. Cl. 438/106; 438/396; 257/678

(57) ABSTRACT

A method for preparing an insulating packaging material for a container is disclosed. A first layer of insulating material can be placed around a container, a second layer of heat-shrinkable material can be placed around the first layer and heat can be applied to heat-shrink the layer and conform the label to the contours of the container. The insulating packaging material can retain its hot and cold insulative properties after being heat-shrunk. The insulating packaging material can be used as a label.

### CROSS-REFERENCE TO RELATED APPLICATION

This application claims priority under 35 U.S.C. § 120 to U.S. Provisional Application No. 60/650,542, filed on Feb. 7, 2005, which is incorporated herein by reference in its entirety.

### FIELD OF THE INVENTION

The invention relates to a process for preparing insulated packaging comprising a thermal insulating layer and a heat shrinkable layer.

### BACKGROUND OF THE INVENTION

Several patents and publications are cited in this description in order to more fully describe the state of the art to which this invention pertains. The entire disclosure of each of these patents and publications is incorporated by reference herein.

Shrink labels provide excellent shelf appeal and maximum advertising space on a container. However, conventional shrink labels do not provide adequate insulation for a container.

U.S. Pat. Nos. 3,979,000; 4,034,131; 4,038,446 and 4,071,597 disclose protective heat-shrunk cellular sleeves comprising laminates of closed cellular polystyrene compositions and non-cellular polymeric layers. However, these shrink foam labels provide poor graphics quality and very low insulation value.

Insulated enclosures for containers are known. See e.g., U.S. Pat. No. 4,871,597. This enclosure includes a first, or innermost fabric layer, a second innermost insulating layer which includes a polymeric foam, a third innermost metallized polymer film reflective layer, and an outermost fabric mesh layer. However, the use of four different layers, although providing good insulation for the container, can be cumbersome to prepare, which limits the usability of the container.

U.S. patent application Ser. No. 09/832503 discloses an insulated label that comprises a thermal insulating layer laminated to at least one heat-shrinkable face material.

There exists a need to develop an insulated packaging material that is inexpensive to manufacture and apply to packages, but is thick enough to provide adequate insulation and thin enough to be flexible, and provide excellent graphics quality. Such material can provide an insulated packaging material that is easy to apply to containers and provides excellent graphics quality and can be used as an insulating shrink label. It is also desirable to develop such a material that may be heat-shrunk to fit over containers with simple and/or complex contours without losing insulation properties.

### BRIEF SUMMARY OF THE INVENTION

The invention includes a method that can be used for preparing an insulated packaging material for a container comprising a first layer, a second layer; or produced by applying a first layer to the outside of a container engaging a sidewall portion of the container to cover the surface or a portion of the surface; applying a second layer to or around the first layer to engage the inner surface of the second layer to the outer surface of the first layer; and shrinking the second layer that is applied to or around the first layer wherein the first layer comprising or produced from a thermal insulating material; the second layer comprising or produced from a heat-shrinkable material; and the shrinking causes the first layer and the second layer to conform to the contours of the container. Preferably the second layer is shrunk around the first layer without significantly compressing the first layer. Also preferably, after shrinking the second layer has a surface area greater than that of the first layer thereby covering the entire area of the first layer and at least one portion of the surface of the container that is not covered by the first layer.

This invention also includes a packaging system comprising a container and an insulating packaging material (e.g. a shrink label) prepared by the method disclosed above or includes a container that can be used for storing a food or beverage insulated with the insulating packaging material. The packaging systems and containers can include beverage cans and polyester blown bottles.

### DETAILED DESCRIPTION OF THE INVENTION

The definitions herein apply to the terms as used throughout this specification, unless otherwise limited in specific instances.

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such.

The insulated packaging material can comprise a thermal insulating layer. Thermal insulating materials can have a structure that provides for air spaces in the structure, thus providing the insulating properties. The thermal insulating layer can have a thermal resistance, as measured in units of insulation, or CLO, of greater than 0.05. The CLO unit is defined as a unit of thermal resistance of a garment. The SI unit of thermal resistance is the square-meter kelvin per watt (m²·K/W) (See “Textile Terms and Definitions”, Tenth Edition, The Textile Institute, (1995), pp. 66, 350). Although CLO is defined in terms of a garment, this measurement can be used to describe the thermal resistance of any textile system, and is used herein to describe the thermal resistance of the thermal insulating layer of the invention. CLO values depend on the material used for the insulating layer and its thickness. Of note are packaging materials wherein the insulating layer has a thermal resistance of from 0.05 CLO (0.0077 m²·K/W) to 1.0 CLO (0.154 m²·K/W), alternatively to 0.9 CLO (0.139 m²·K/W), alternatively to 0.7 CLO (0.108 m²·K/W), alternatively to 0.5 CLO (0.07 m²·K/W). CLO values of labels made without the thermal insulating layer of the present invention are below the thermal resistance indicated herein (0.05 CLO, or 0.0077 m²·K/W).

The thermal insulating layer may comprise an organic thermoplastic fiber based material comprising polyester, polyethylene or polypropylene. In a preferred embodiment, the thermal insulating layer is a fiberfill batt comprising polyester. A fiberfill batt sold as THERMOLITE® Active Original by Koch Industries of Wichita, Kans. (Koch) can be used in the invention. An example of a fiberfill batt that is suitable for use in the invention has an areal weight in the range of from 10 gm/m² to 200 gm/m², and a bulk density of less than 0.3 gm/cm³ prior to its application to the container. Alternatively, the thermal insulating layer may comprise melt blown fibers, such as melt blown polyolefins (available, for example, as THINSULATE®, by 3M of Minneapolis, Minn. (3M)).

Many other variations of insulating material for the thermal insulating layer can be used with the present invention. For instance, the thermal insulating layer may comprise a foam. The foam may be polyurethane or polypropylene, polyethylene or any other foam composition as known in the art. Alternatively, the thermal insulating layer may be made of an inorganic thermoplastic fiber-based material comprising glass wool, borosilicate glass or rockwool.

Alternatively, the thermal insulating layer may comprise a knit fabric, made, for example from a tetrachannel or scalloped oval fiber, sold under the trademark COOLMAX® from Koch. Or the thermal insulating layer may be a woven or fleece material. The insulating layer could also comprise some sort of nonwoven, such as felt, or a highloft nonwoven or needled nonwoven fabric.

The insulating material of the present invention is greater than 0.0075 inch (0.0190 cm) thick, so that it is thick enough to provide adequate insulation for a package. However, it is desirable that the packaging material is thin enough to be flexible, for example, less than 0.125 inch (0.318 cm). Such insulating packaging materials have CLO values above 0.05.

The insulating layer may consist of a single layer of insulating material as described above. However, it can also be a laminate with at least one additional layer comprising face material to the thermal insulating layer. Accordingly, the invention contemplates an insulating layer as described above that further comprises at least one additional layer comprising a face material. The face material may be film, paper, foil, and/or fabric.

The face material is applied to one or both of the faces of the insulating material. For example, the face material may enhance the structural integrity of the insulating layer so that it can be more effectively applied to the container, particularly by automated machines. The optional use of one or more layers of face material preferably does not affect the thickness of the packaging material substantially, because the thickness of the face material is insignificant compared to the total thickness of the packaging material.

The thermal insulating material can be laminated to at least one face material. By “lamination” is meant uniting layers of material by an adhesive, such as a hot melt adhesive, or other means. One suitable hot melt adhesive is a reactive polyurethane such as Type NP-2075-T by HB Fuller of St. Paul, Minn., USA. Another suitable adhesive is ADCOTE® offered by the Morton Division of Rohm and Haas Company, Philadelphia, Pa., USA. Heat-sealable layers in multilayer structures are also suitable for adhering the face material to the insulating material.

For example, the thermal insulating material is laminated between two sheets of film, paper, foil or fabric to form an insulating layer of the invention. When two sheets of face material are used, both sheets may comprise the same type of face material, or the sheets of face material may be different from each another. A film useful for the face material is preferably made of a thermoplastic material comprising a material selected from polyester (such as polyethylene terephthalate (PET)), polyethylene or polypropylene. The film may be a monolayer film or a multilayer film. Such films can be prepared by methods known in the art including coextrusion, lamination, extrusion coating and the like. The film may be optionally metallized film.

In an embodiment, a coextruded, heat sealable, polyester film may be used as face material. Such suitable films include those of the type sold by DuPont Teijin Films of Wilmington, Del. (DuPont Teijin) under the trademark MELINEX® 301-H. These films comprise polyethylene terephthalate coextruded with an isophthalic acid-based copolyester as a heat-sealable layer. Depending on the thickness, the heat-sealable layer comprises from about 10 to about 50% of the total film thickness; from about 15 to about 30% is preferred.

The face material may also be a heat-shrinkable film (shrinks by length and/or width when subjected to heating). Preferably, when used, a heat shrinkable face material shrinks preferentially in one direction when heat is applied to the face material, such as lengthwise or “hoopwise” to surround a container. Suitable thermoplastic films may also include poly(vinyl chloride), polyethylene glycol (PEG), glycol-modified PET (PETG), such as Eastman's EASTAR™ PETG copolyester 6763 (Eastman Chemical Company, Kingsport, Tenn. (Eastman)), PET/PETG blends, amorphous PET, oriented polystyrene (OPS) and oriented polypropylene (OPP).

A coextruded, solvent sealable, heat shrinkable polyester film (such as MYLAR® D868 film) can also be used. The outer surface layers of the film can comprise a polyester copolymer and are receptive to commonly used welding or sealing solvents for the manufacture of shrink sleeves, such as tetrahydrofuran (THF). For a MYLAR® D868 film having a thickness of 2 mil (0.0051 cm), the shrinkage in the long or “hoop” direction is in a range from 60 to 80% and the shrinkage perpendicular to the hoop direction is in a range from 0 to 10%. Thermal shrinkage is determined by measuring the length and width dimensions of a film sample, immersing the sample in 100° C. (212° F.) water bath for 30 minutes and then measuring the length and width to calculate the amount of film shrinkage.

Preparation of a webstock comprising an insulating material and a layer of face material suitable for forming the insulating layer can be accomplished by the following method. A sheet of insulating material used for the thermal insulating layer, such as fiberfill batt, is fed from a supply roll. An adhesive is applied between the face material and the thermal insulating material. This adhesive is applied by one or more coating rollers that are positioned between feed rolls and calender rolls. The adhesive may be applied using a pair of kiss roll and pan assemblies, known in the art, and positioned between feed rolls and calender rolls. Alternatively, adhesive may be applied with a sprayer or with an extruder. Face material can be fed from supply roll(s) and coated with adhesive and laminated to at least one surface of the fiberfill batt. Alternatively, a multilayer film comprising a heat-sealable layer is used for the face material.

The sheet of the thermal insulating material and one or two sheets of face material can be fed into a calender roll nip between a pair of calender rolls. The rolls may be heated to activate any heat-sealable materials or adhesives to effect adherence of the insulating material to the face material. If a heat-shrinking face material is present, the calender rolls are either not heated or are heated below the heat-shrink initiation temperature so as not to activate shrinkage of the face material. The calender rolls are displaced from one another at a distance appropriate to create a nip pressure suitable for lamination. Alternatively, a single sheet of face material can be laminated to one surface of the insulating material in one laminating operation and a second sheet of face material can be laminated to the opposite surface of the insulating material in a second laminating operation. The laminated packaging material is formed and then pulled through the process equipment by means of a take-up roll.

An insulating layer with a thickness of greater than 0.0075 inch (0.0190 cm), notably with a thickness in the range of from 0.0075 inch (0.0190 cm) to 0.125 inch (0.318 cm), alternatively to 0.100 inch (0.254 cm), alternatively to 0.07 inch (0.1778 cm), alternatively to 0.06 inch (0.1524 cm) is thus produced.

The formation of the insulating webstock may be followed by cutting the webstock to desired widths with a hot knife, which seals the edges of the webstock. Alternatively, the edges may be sealed via solvent welding. The desired width is generally the dimension of the label that will be parallel to the axis of the desired container.

The term “sealed edge” means that the margin of the webstock is closed so that air and fluid cannot pass through that portion of the webstock. For example, the structure of the insulating material in the region of the sealed edge is altered by the application of heat, ultrasonics and/or solvent so that the air spaces in the material are closed. In some cases, when the insulating packaging material is laminated between two sheets of film face material to form the insulating layer, the two films are joined together at the edges of the webstock and fused into one body to create a permanent seal. In some cases, it may be desirable that the edges of the sheets of face material extend beyond the edges of the insulating packaging material so that the sheets of face material are in direct contact with each other to facilitate joining them together.

The insulating material, at this stage still in the form of a long roll of webstock, may then be cut into shorter pieces, which may preferably have sealed edges also, having lengths suitable to wrap circumferentially around the desired containers. Alternatively, cutting the insulating material to the desired length from the roll of webstock occurs as part of the operation of applying the insulating layer to the container.

When a heat-shrinkable face material is used as part of the insulating layer, the insulating layer can be applied to the container so that the face material is on the inner surface of the insulating layer so that it is facing the outer surface of the container.

An insulating material as described herein may be of the type sold by E.I. du Pont de Nemours and Company (DuPont) under the trademark Cool2go®.

The second layer is heat-shrinkable so that the insulating packaging material may be formed around containers with regular and irregular contours.

Preferred heat-shrinkable films that may be used for the second layer include polyester, polypropylene or polyethylene. Suitable heat-shrinkable thermoplastic films may also include poly(vinyl chloride), polyethylene glycol (PEG), glycol-modified PET (PETG), such as EASTAR™ PETG copolyester 6763 from Eastman, PET/PETG blends, amorphous PET, oriented polystyrene (OPS), such as LABELFLEX® or POLYFLEX® from Plastic Suppliers, Inc. of Columbus, Ohio USA, and oriented polypropylene (OPP). A polyester heat shrinkable film sold under the trademark MYLAR® D868 by DuPont Teijin is also suitable. Heat shrink films that are activated by steam, radiant heat and/or microwave radiation may be used in the present invention.

The heat shrinkable layer may be formed of a heat shrink material that shrinks preferentially in one dimension, such as lengthwise or “hoopwise” to surround a container. This type of heat shrink material generally has better visual aesthetics due to more predictable post-shrink size and less distortion than materials that shrink both latitudinally and longitudinally. In addition, generally a lesser amount of directional-preferentially shrinking material is required to cover a container surface.

This shrink layer may be printed on the outside surface (i.e. the surface that faces away from the insulating layer and is the outermost surface of the resulting label) or printed on the inside surface so that the printed surface is on the interior of the resulting label (reverse printed). Typically, either surface printing or reverse printing is carried out on a web of film before it is formed into the heat-shrinkable layer by cutting and/or applying to the container.

Upon application of heat, such as by blowing heated air or steam onto the container in a shrink tunnel, the heat shrinkable film of the second layer causes the insulating label to shrink to fit around the contours of the container.

In one embodiment, a non-heat-shrinking material such as a non-heat-shrinking film is laminated to the insulating layer as a face material. In this embodiment, the heat-shrinkable layer is the only material that is affected by application of heat.

Alternatively, the optional face material of the insulating layer may also be heat-shrinkable. Here, the heat-shrink layer may be prepared using the same heat shrinkable material optionally used as face material for the insulating layer. Alternatively, it is also within the scope of the present invention to use different heat-shrinkable materials for the heat-shrinkable second layer and the face material of the insulating first layer. Of note is an embodiment wherein the heat shrinkable face material of the first layer has a different thermal shrinkage and shrinks to a different degree than the heat shrinkable film of the second layer when face material of the first layer and the heat shrinkable film of the second layer are heated to the same temperature. When heat shrinkable films with different thermal shrinkage properties are used, one for the face material of the insulating layer and one for the heat-shrinkable layer, a more uniform shrinkage around a container may be obtained. For example, the face material on the insulating layer may shrink more than the heat-shrinkable layer, such that the label stock more uniformly conforms to the container shape after heat-shrinking. This could be helpful to more uniformly cover a container surface where the insulating material makes it difficult to heat both the heat-shrink face material of the insulating layer and the heat-shrink layer to the same temperature contemporaneously. This is also useful to minimize the compression of the insulating layer during heat-shrinking, so that the maximum insulating capability is provided. Moreover, for applying labels to containers with unusual profiles, it can be advantageous to modify the shrink initiation temperature, shrinkage rate, or the maximum obtainable shrinkage of either the inner face layer or the outer face layer to obtain a tight and wrinkle-free label.

The second layer preferably has a surface area greater than that of the first layer so that it covers the entire area of the first layer and contacts at least one portion of the surface of the container that is not covered by the first layer. For example, the heat-shrinkable layer may be sized so that it contacts the sidewall of the container above and/or below the insulating layer. In some cases, the heat-shrinkable layer contacts the sidewall above the insulating layer (near the open end of the container) and below the insulating layer (near the closed end of the container). In some cases, the heat-shrinkable layer contacts the bottom outer surface of the container (i.e. the closed end of the container) and is shrunk around at least a portion of the bottom of the container. In some cases, the heat-shrinkable layer may contact the container at the perimeter of the opening and be shrunk around the perimeter.

An insulating packaging material (e.g. label) according to the present invention is preferably sealed so that fluid, such as water, cannot penetrate the edges or face thereof. Fluid penetration may have a negative effect on the insulating capability of the label. As indicated above, the edges of the insulating layer may be sealed as part of its production. Preferably, the heat-shrinkable layer is impervious to fluids so that it will prevent the fluids from reaching the face of the insulating layer. In addition to conforming the label to the container, the outer heat-shrinkable layer may be useful in preventing fluid penetration to the insulating layer by forming a tight seal around the perimeter of the label, particularly if it has a surface area greater than that of the insulating layer.

The first layer comprising insulating material as described above is applied to the outside of a container circumferentially engaging a sidewall portion of the container so as to cover a significant portion of the surface area of the container. The insulating layer may be applied by hand or by a machine or combination of machines. Preferably, the insulating layer is applied by an automated machine adapted to that purpose. For example, a flat sheet of the desired dimensions to encircle the container having a leading edge and a trailing edge may be wrapped around the container so that the trailing edge is placed adjacent to, or overlaps, the leading edge. In some cases, it may be desirable to adhesively attach the inside face of the insulating layer to outside surface of the container. Alternatively, the leading edge and trailing edge of the insulating layer are joined together after it is wrapped around the container. The joining may be accomplished by application of heat to effect a heat-seal, application of adhesive, or application of solvent in a solvent welding process. For example, adhesive applied to the inside face of the leading edge of the insulating layer adheres the insulating layer to the outside surface of the container, the insulating layer is wrapped around the container and adhesive applied to the inside face of the trailing edge adheres the trailing edge to the outside face of the leading edge in the area where the edges overlap. A strip that overlaps and attaches to both edges, such as adhesive-faced tape may also join the edges together. Alternatively, in other cases, the insulating layer may have sufficient rigidity that it remains wrapped around the container without bonding or adhering prior to application of the second layer as described below. In still other cases, the insulating layer may be held around the container by mechanical means prior to application of the second layer. For example, the insulating layer may be held around the container by a cavity shaped to hold the insulating layer around the container. Alternatively, a suitable machine, such as one used for applying labels, may be configured to hold the insulating layer around the container until the second heat-shrink layer is sequentially wrapped around it.

The insulating layer may be applied to a container, such as a beverage container, by normal roll-fed labeling machines, such as a Trine 4500 Labeler available from Trine Labeling Systems of Fullerton, Calif. Alternatively, the insulating layer can be applied by a cut/stack labeler such as the Canamatic made by Krones AG of Neutraubling, Germany. Standard hot melt adhesives such as Euromelt 385 from the Henkel Group of Dusseldorf, Germany, or HM 1672 from the H.B. Fuller Company of St. Paul, Minn., can be used to adhere the insulated label to the container.

Alternatively, the insulating layer may be formed into a generally cylindrical open-ended sleeve or tube that is placed over the container. An example of a thermal insulating layer that can be used in this configuration is a knit tube that is cut to length and slipped over the container so that it is wrapped around the outer circumference of the container. The insulating material is typically formed into a sleeve by joining opposite edges before placing the insulating webstock around the container. Methods suitable for joining the opposite edges are discussed above. As one method, a sleeve may be formed by looping the webstock, optionally around a mandrel, and joining and sealing the cut edges together in a solvent welding process. After the sleeve is formed, either it is dropped over the container or the container is slid into the sleeve. Alternatively, the sleeve may have an axial slit so that the container may be inserted into the sleeve through the slit.

After the insulating layer is applied to the container, a second layer capable of being heat shrunk is applied to the container over the insulating layer. The second layer, comprising heat-shrinkable material, is applied around the first layer so that the inner face of the second layer circumferentially engages the outer surface of the first layer. It may be applied as a flat sheet wrapped around the first insulating layer or as a sleeve or tube slipped over the insulating layer. For example, the heat-shrinkable layer may comprise oriented polystyrene. Methods for applying the second heat-shrinkable layer are similar to those described above for the insulating layer.

The heat-shrinkable layer in the form of a sleeve can be applied using an American Fuji Seal Inc. Intersleeve shrink applicator or a Krones Sleevematic labeling machine available from Krones AG of Neutraubling, Germany.

Alternatively, a “roll on, shrink on” (ROSO) approach can be used to apply the second heat-shrinkable layer. In this approach, a flat sheet of heat-shrinkable material is supplied from a roll of webstock and wrapped around the container. The leading edge of the sheet is first secured to the container with hot melt adhesive, the sheet is wrapped around the container and then the trailing edge is secured with hot melt adhesive. For example, the trailing edge of the sheet is placed so that it overlaps with the leading edge and then secured by the adhesive. During this operation, the heat-shrinkable layer is cut from the roll of webstock to the proper length to wrap around the container. The “rolled on” heat-shrinkable layer is then shrunk to fit the container by applying dry heat or steam, as described below. This ROSO approach can be accomplished using automated machinery, with a suitable labeling machine being the Trine 4500 from Trine Labeling Systems of Fullerton, Calif.

The heat-shrinkable layer may be shrunk by the application of heat in a shrink tunnel, causing it to conform to the container, holding the insulating sleeve underneath it securely to the container and providing a neat, finished appearance. Depending on the mass of the material and the dwell time in the shrink tunnel, the heat may be provided by hot air or steam at temperatures ranging from about 85° C. to about 260° C. The result is a shrink label comprising the insulating layer and the heat-shrinkable layer wrapped around a container.

There is also provided an insulated packaging system comprising a container wrapped with an insulating packaging material (label) so as to cover a significant portion of the surface area of the container and prepared by the process described herein. Materials suitable for use in the container include metal such as aluminum, glass, plastic, paperboard and the like. The container may be a can or bottle suitable for safe storage and consumption of beverages and foods. Alternatively, the container may be a cup. In the case of a cup, the cup may be of the type commonly used for single serving sizes of hot beverages, such as a disposable coffee cup. Alternatively, the cup may be a carton, such as an ice cream carton or other food carton. In many cases, the container can also have a closure that seals the opening of the container until the contents are to be accessed by the consumer. Such closures include caps such as screw caps, friction-fit caps and the like that are well known in the packaging art. Closures also include “pop-top” openings for cans or plastic reclosable fitments. Closures also include peelable lidding films that are hermetically sealed to the container opening.

Alternatively, the insulating layer is applied to a container that has been designed to have suitable indentations to hold the insulating layer in place prior to heat shrinking the heat-shrinkable sleeve. Flanges or raised areas on the container can serve a similar function. In addition to holding the insulating layer in place, such indentations or flanges may help to prevent undesired compression of the insulating layer upon heat-shrinking.

If the container, such as a cup, is of a conic section design, where the top circumference is significantly larger than the bottom circumference, the first insulating layer of the present invention may be shaped in a similar conic section shape so as to fit the cup snugly. The second heat-shrinkable layer may also be shaped in a similar conic shape and then heat-shrunk in place around the cup and insulating layer.

The primary function of the insulating packaging material as described herein is to maintain the temperature of the contents of the container for a longer period of time than a noninsulated container would. For example, the contents of insulated containers heated above ambient temperature will decline in temperature at a slower rate than those of a noninsulated container. Similarly, cold contents will remain cold longer in the insulated container. Another benefit of the insulated container is to reduce the exposure of the consumer to high temperatures when handling a container with heated contents.

The ability of the insulating packaging material or label to insulate containers may be applied beyond maintaining the temperature of a heated beverage or food hotter for a longer period of time. Many foods and beverages are pasteurized or heated to a specified temperature for a specified time period (such as 160° F. for five or more minutes) to kill bacteria and prevent food or beverage contamination. Frequently, bottlers and other food container fillers heat the contents of the container to temperatures much higher than the minimum temperature required (e.g. up to 190° F.) so that the container contents will stay above the minimum temperature (e.g. 160° F.) for the required time, because convection heat losses cause the temperature to go down over time. The insulating packaging material can maintain the container contents at a higher temperature over time, such that efficiencies may be obtained. For example, the maximum heating temperature may be lowered, which results in energy savings. Alternatively, these efficiencies may also mean that different container materials may be used that heretofore were avoided because they could not withstand the higher heating temperatures.

In addition to its function as an insulating wrap for a container, the insulating packaging material can also function as a label. As indicated above, the second sleeve can be printed. The printing can be used to provide information to the consumer and/or provide a pleasing appearance to the package. The heat-shrinkable layer of this invention provides for printed graphics of higher quality than that achieved using prior foam protective labels.

The following examples are provided to describe the invention in further detail. These examples, which set forth a preferred mode presently contemplated for carrying out the invention, are intended to illustrate and not to limit the invention.

The test methods used for assessing the insulating materials (labels) of the invention compared to standard labels are described below.

### Test Methods

Insulation thickness is measured using a Mitutoyo Absolute Electronic—Code #7004 thickness gauge.

### Cooling Duration Comparison Test

Materials Used

Two identical containers (e.g. bottles or cans with appropriate closures).

Noninsulated label of the correct size for the container.

Insulating label of the correct size and desired insulation thickness for the container.

Constant temperature bath and circulation system comprising a Lauda Ecoline #RE:206, manufactured by Brinkman Instrument, Westbury, N.Y. and about 7 feet of food grade Tygon® tubing of ½-inch outside diameter and ⅜-inch inside diameter.

Calibrated thermocouple accurate to 0.1° F. such as Fluke 52II Digital Thermometer.

Environmental chamber capable of maintaining an environment at a given temperature and humidity (e.g. 70° F. and 40% relative humidity (RH)).

Procedure

The noninsulated and insulated labels were applied to the test containers. The containers were filled with equal amounts of water and capped.

An ice and water bath was set up in the 70° F./40% RH environmental chamber and both containers were placed in the ice-water bath for an hour or more or until they were completely equilibrated.

The constant temperature bath was set up in the 70° F./40% RH environmental chamber. Tygon® tubing was attached to the constant temperature bath to form a loop for circulating the constant temperature solution. The constant temperature bath was set to 85° F. and allowed to run until it was completely equilibrated.

The containers were removed from the ice bath and dried.

The timer was started, the containers were uncapped, and the initial temperature was measured and recorded. The containers were recapped.

Five (5) coils of the Tygon® tubing were wrapped snugly around each container and the water circulation through the constant temperature bath was started.

At five-minute intervals, the caps were taken off and the temperature in the center of each container was measured, disturbing the water as little as possible. These measurements were continued until the internal temperature in each container exceeded 60° F.

For a 32° F. to 55° F. Comparison:

The time it took for each container to reach 55° F. was determined from the plot or a trendline equation derived from an XY scatter plot of the data.

The comparison of the insulated label to the noninsulated label (“% colder longer”) can be calculated according to the equation (1):
100(Timeₑₓ−Timeₛₜ)/Timeₛₜ=% colder longer (1)
wherein Timeₛₜ was the time for the noninsulated container to reach 55° F.; and Timeₑₓ was the time for the insulated container to reach 55° F.

For a 42° F. to 55° F. Comparison:

The time for the temperature of the water in each container to rise from 32° F. to 42° F. was determined.

In the polynomial equation derived from the previously determined trendlines, x+t was substituted for x, where t was the time it took each container to reach 42° F.

The temperature was recalculated with the new equation starting at Time 0. This did not change the data but rather only shifted the lines to the same starting point.

The data was replotted as described above, and the percentage of time for which the water in the container stayed colder longer was calculated according to equation (1).

### Insulation Determination

For the following Examples, the initial CLO of the material used for the insulating layer was measured on a “Thermolabo II”, which is an instrument with a refrigerated bath, commercially available from Kato Tekko Co. L.T.D., of Kato, Japan. The bath was obtained from Allied Fisher Scientific of Pittsburgh, Pa. Lab conditions are 21° C. and 65% relative humidity. The sample was a one-piece sample measuring 10.5 cm×10.5 cm.

The thickness of the sample (in inches) at 6 gm/cm² was determined using a Frazier Compressometer, commercially available from Frazier Precision Instrument Company, Inc., of Gaithersburg, Md. To measure thickness at 6 g/cm², the following formula was used to set psi (pounds per square inch) (kilograms per square centimeter) on the dial: (6.4516 cm²/in²) (6 g/cm²)/453.6 g=0.8532 lb/in².

A reading of 0.8532 on the Frazier Compressometer Calibration Chart (1 in., or 2.54 cm. diameter presser foot) showed that by setting the top dial to 3.5 psi (0.2 kilograms per square centimeter), thickness at 6 g/cm² was measured.

The Thermolabo II instrument was then calibrated. The temperature sensor box (BT box) was set to 10° C. above room temperature. The BT box measures 3.3 inch×3.3 inch (8.4 cm×8.4 cm). A heat plate measuring 2 inches×2 inches was placed in the center of the box, and was surrounded by styrofoam. Room temperature water was circulated through a metal water box to maintain a constant temperature. A sample was placed on the water box, and the BT box was placed on the sample. The amount of energy (in watts) required for the BT box to maintain its temperature for one minute was recorded. The sample was tested three times, and the following calculations are performed:
Heat Conductivity (W/cm° C.)=(W)(D×2.54)/(A)(ΔT) (2)
wherein W=Watts; D=Thickness of sample measured in inches at 6 g/cm². (6 g/cm² was used because the weight of the BT box was 150 gm, the area of the heat plate on the BT box was 25 cm²); 2.54 is the factor for conversion between inches and centimeters; A=Area of BT Plate (25 cm); and ΔT=10° C.
CLO=Thickness×0.00164/Heat Conductivity

The value of 0.00164 was a combined factor including the correction of 2.54 (correcting thickness from inches to centimeters) times the correction factor of 0.0006461 to convert thermal resistance in cm²×° C./Watts to heat conductivity. To convert heat conductivity to resistance, conductivity was put in the denominator of the equation.

### EXAMPLE 1

An insulated packaging layer was made according to a process in which the thermal insulating material and the face material were adhered together using a thermal lamination process. A fiberfill batt of the type sold by Koch Industries under the trademark THERMOLITE® Active Original was used as the thermal insulating material. The fiberfill batt had an areal weight of 100 g/m² at a specified thickness of 0.25 inch (0.63 cm), or a bulk density of 0.013 g/cm³. This batt was reduced in thickness, via needling and calendering, to about 0.030 inch (0.0012 cm).

The films used as the face material were of the type sold by DuPont Teijin under the trademark MELINEX® 301-H. In this Example, one sheet of face material was 1.2 mils (0.0012 inch, or 0.0030 cm) thick and a second sheet of face material was 0.48 mils (0.00048 inch, or 0.00122 cm) thick. The films were laminated to the fiberfill batt with the heat-sealable layers in contact with the batt. The heat-sealable layers were activated at temperatures from 240 to 350° F. (116 to 177° C.), summarized in Table 1 below. The effect of using different activation temperatures was to give greater thickness and greater insulation values at the lower temperatures, and less thickness and lower insulation values at the higher temperatures. The final webstock thickness, after lamination, was 0.025 inch (0.064 cm).

TABLE 1

| | | |
|---|---|---|
| | | Thermal |
| Temperature | Thickness | Resistance |

| ° F. | ° C. | inch | cm | CLO | m² · K/W |
|---|---|---|---|---|---|
| 240 | 115 | 0.041 | 0.104 | 0.272 | 0.042 |
| 250 | 121 | 0.036 | 0.091 | 0.226 | 0.035 |
| 280 | 138 | 0.03 | 0.076 | 0.199 | 0.030 |
| 310 | 154 | 0.027 | 0.069 | 0.17 | 0.026 |
| 350 | 177 | 0.024 | 0.061 | 0.141 | 0.021 |

The laminated insulating material described above was made and cut to dimensions suitable for wrapping around a 12-ounce (355 ml) beverage can (approximately 10 cm by 21 cm) to form an insulated layer used in this invention. Another insulating layer cut to dimensions suitable for wrapping around a 16-ounce (473 ml) beverage can (approximately 12.7 cm by 21 cm) was made from this laminated insulating material. Other insulating layers of the appropriate dimensions suitable for wrapping around a blown polyester beverage bottle (approximately 5 cm, 8 cm or 10 cm by 20.5 cm) were also made from this laminated insulating material.

Similar insulated stock as that described above is of the type sold by DuPont under the trademark Cool2go®.

### EXAMPLE 2

The insulating layer of Example 1 was applied by hand using transfer tape, such as 9415PC available from 3M, to adhere the insulating layer to a can suitable for storing a carbonated beverage. The insulating layer was applied around the right-cylindrical portion of the can with the thinner face material in contact with the can. A heat-shrinkable sleeve comprising oriented polystyrene with suitable shrink characteristics (available under the trademark Polyflex from Plastic Suppliers, Inc. of Columbus, Ohio) was also applied over the insulated container by hand. This sleeve covered the entire insulating layer and extended about 1.3 cm above and below it on the neck-in portions of the can. The insulating label system comprising the insulating layer and the heat-shrinkable layer was then shrunk by placing the can in a 170° C. oven for ten seconds.

### EXAMPLE 3

The insulating layer of Example 1 was applied by hand using transfer tape, such as 9415PC available from 3M, to adhere the insulating layer to a beverage can with the thinner face material in contact with the can. A heat-shrinkable sleeve, comprising oriented polystyrene was also applied over the insulating layer container by hand as described in Example 2. The label system comprising the insulating layer and the heat-shrinkable layer was then shrunk by heating with a hot air gun set at 450° F.

### EXAMPLE 4

The 5-cm-wide insulating layer of Example 1 was applied by hand using transfer tape, such as 9415PC available from 3M, to adhere the insulating layer to a blown polyester bottle suitable for storing a carbonated beverage. The insulating layer was applied around the label area portion of the bottle below the neck-in area with the thinner face material in contact with the bottle. A heat-shrinkable sleeve comprising oriented polystyrene with suitable shrink characteristics (available under the trademark Polyflex from Plastic Suppliers, Inc. of Columbus, Ohio) was also applied over the insulated container by hand. This sleeve covered the entire insulating layer and extended about 2.5 cm above it onto the neck-in area and about 9 cm below it, extending to the bottom of the bottle. The insulating label system comprising the insulating layer and the heat-shrinkable layer was then shrunk by placing the can in a 175° C. oven for ten seconds.

Other insulated bottles were prepared similarly, using the 8-cm and 10-cm insulating layers of Example 1.

### EXAMPLE 5

The insulating layer of Example 1 was applied to a beverage container by a normal roll-fed labeling machine, such as a Trine 4500 Labeler available from Trine Labeling Systems of Fullerton, Calif. A standard hot melt adhesive such as HM1672 from H.B. Fuller was used to adhere the insulating layer to the container.

After the insulating layer was applied to the container, a second layer comprising oriented polystyrene capable of being heat shrunk was applied to the container over the insulating layer. The heat-shrinkable layer was in a sleeve configuration and was applied using an Intersleeve label application machine from American Fuji Seal, Inc. of Bardstown, Ky. The shrink sleeve was shrunk with hot steam at 212 to 500° F. in a shrink tunnel, depending on container size and throughput rates, causing the heat-shrinkable sleeve to conform to the can, holding the insulating layer underneath it securely to the container and providing a neat, finished appearance.

### EXAMPLE 6

The insulating layer described in Example 1 was applied to a beverage can by a cut/stack labeler such as the Canamatic made by Krones AG of Neutraubling, Germany. A standard hot melt adhesive such as HM1672 from H.B. Fuller was used to adhere the insulating layer to the container.

A “roll on, shrink on” approach to applying the shrinkable layer comprising oriented polystyrene was used, using the Trine 4500 from Trine Labeling Systems. The label system was then shrunk onto the can in a shrink tunnel by application of hot air or steam.

While certain of the preferred embodiments of the present invention have been described and specifically exemplified above, it is not intended that the invention be limited to such embodiments. Various modifications may be made without departing from the scope and spirit of the present invention, as set forth in the following claims.

1. A method for preparing an insulated packaging material for a container comprising applying a first layer to the outside of a container engaging a sidewall portion of the container to cover the surface or a portion of the surface; applying a second layer to or around the first layer to engage the inner surface of the second layer to the outer surface of the first layer; and shrinking the second layer that is applied to or around the first layer; wherein the shrinking causes the first layer and the second layer to conform to the contours of the container.

2. The method of claim 1 wherein the first layer comprises or is produced from a thermal insulating material.

3. The method of claim 1 wherein the second layer comprises or is produced from a heat-shrinkable material.

4. The method of claim 1 wherein the first layer circumferentially engages a sidewall portion of the container and the second layer circumferentially engages the outer surface of the first layer.

5. The method of claim 1 wherein the second layer is shrunk around the first layer without significantly compressing the first layer.

6. The method of claim 1 wherein the second layer after shrinking has a surface area greater than that of the first layer and preferably covers the entire area of the first layer and at least one portion of the surface of the container that is not covered by the first layer.

7. The method of claim 1 wherein the thermal insulating material has a thickness greater than 0.0075 inch prior to heat shrinking and preferably comprises a fiberfill batt, a foam, or both.

8. The method of claim 1 wherein the thermal insulating material has a thermal resistance greater than 0.0077 m²·K/W.

9. The method of claim 1 wherein the first layer further comprises at least one additional layer comprising a face material which is film, paper, foil, or fabric and is preferably a film or metallized film comprising polyester, polyethylene or polypropylene, poly(vinyl chloride), polyethylene glycol, polyethylene terephthalate/polyethylene glycol blends, amorphous polyethylene terephthalate, oriented polystyrene, oriented polypropylene, or combinations of two or more thereof.

10. The method of claim 9 wherein the face material is a heat-shrinkable film that shrinks preferentially in one direction when heat is applied to the face material.

11. The method of claim 1 wherein the second layer comprises a heat-shrinkable film that shrinks preferentially in one direction when heat is applied and optionally further comprises a heat-shrinkable film comprising polyester, polyethylene or polypropylene, poly(vinyl chloride), polyethylene glycol, polyethylene terephthalate/polyethylene glycol blends, amorphous polyethylene terephthalate, oriented polystyrene, oriented polypropylene, or combinations of two or ore thereof.

12. A packaging system comprising a container and an insulating packaging material produced by the method of claim 1.

13. A container insulated with an insulating packaging material prepared by the method of claim 1.

14. The packaging system of claim 12 wherein the container is a beverage can, a blown polyester bottle, or both.

15. The container of claim 13 wherein the container is a beverage can, a blown polyester bottle, or both.
